(19) United States
(12) Patent Application Publication
(10) Pub. No.: US 2002/0118642 A1
(43) Pub. Date: Aug. 29, 2002

(54) Network topology for use with an open internet protocol services platform

(76) Inventor: Daniel Joseph Lee, Salt Lake City, UT (US)

Correspondence Address: MORRISS, BATEMAN, O'BRYANT & COMPAGNI, 136 SOUTH MAIN STREET, SUITE 700, SALT LAKE CITY, UT, 84101, US

(21) Appl. No.: 09/976,672

(22) Filed: Oct. 11, 2001

Related U.S. Application Data
(60) Provisional application No. 60/272,279, filed on Feb. 27, 2001.

(51) Int. Cl. G01R 31/08; G06F 11/00; G08C 15/00

(52) U.S. Cl. 370/230; 370/235; 370/400

(57) ABSTRACT

A switch fabric global information network topology, wherein a switch fabric network matrix provides an Open IP Services Platform at each node thereof, the Open IP Services Platform providing decentralization of network services and a constant trunk size, wherein the switch fabric network matrix eliminates saturation of any communication line, thereby always making bandwidth available, and providing an infinitely scalable network topology.

### CROSS REFERENCE TO RELATED APPLICATION

This document claims priority to, and incorporates by reference all of the subject matter included in the provisional patent application filed Feb. 27, 2001, titled OPEN INTERNET PROTOCOL SERVICES PLATFORM AND TOPOLOGY FOR USE, and all of the subject matter included in the co-pending application titled OPEN INTERNET PROTOCOL SERVICES PLATFORM, and filed Sep. 25, 2001.

### BACKGROUND

1. The Field of the Invention

This invention relates generally to network topologies and their applications. Specifically, the present invention is a new network topology that applies the advantages of an Open IP Services Platform as described in co-pending application titled OPEN INTERNET PROTOCOL SERVICES PLATFORM, wherein the new network topology enables more efficient utilization of network services.

2. Background of the Invention

Access to the Internet or other global information networks is generally becoming a commodity as Service Providers (SPs) and Local Exchange Carriers (LECs) look to new value-added applications and services in order to retain customers, attract new business clients, and generate revenue. Enterprises face a limited supply of certified network administrators, increased demand for high-bandwidth network services, and the need to reduce the total cost of ownership while preserving existing infrastructure investments.

Unfortunately, existing solutions for SPs and LECs fall short in a number of important areas. For example, most customer-premise equipment (CPE) is not Telco quality, thus resulting in inconsistent, unreliable service and problematic service agreements. Next, integration between network devices from a variety of vendors is difficult at best. Furthermore, a lack of extensibility and flexibility makes CPE difficult to scale. New application services can require a large upgrade, or at least a visit to the customer to modify or replace equipment. There are almost always new costs associated with every new piece of Internet Protocol (IP) functionality, as well as additional management issues. Finally, each piece of equipment requires a separate management interface, preventing network-wide visibility.

The issues above all combine to prevent delivery of revenue-generating, differentiated IP services to an increasingly demanding customer base.

Current network designs typically require a discrete piece of equipment for each network function to be performed. For example, an Enterprise will typically include network devices that interface with desktop computers and servers, and connect them to the Internet or other network. The network devices includes servers, switches, routers, bridges, firewalls, load balancers, packet shapers, etc. Managing this wide conglomeration of network devices requires a significant amount of time and vendor-specific expertise.

As network requirements expand and change, the need for specialized network services also changes. For example, repositioning a single network device within a network architecture disadvantageously necessitates both network downtime and a physical presence to make the changes. It is useful to examine a typical network configuration for an Enterprise to better understand the problem.

FIG. 1 is an illustration of a typical network topology 10 of the prior art. The interface between desktops 12 and servers 14 to a network, such as the Internet 16, typically includes network devices or components such as a router 18, a firewall 20, a packet shaper 22, and at least one switch, but where two switches 24, 26 are shown in this figure. Another server 28 might also be part of this interface, when the server is providing network services such as in an SQL server, DNS server, Web server, etc.

Each of the discrete components listed above is disposed within its own “box.” Each box occupies a certain amount of space, or footprint. Furthermore, each box must also have its own power supply.

It would be an advantage over the state of the art to provide network administrators with a network architecture and system tools that would provide a consolidated, flexible, scalable, and less complex management solution that can be customized according to a customer's needs. Such a solution should enable network components, both the hardware and the software, to be included from any vendor. It would also be an advantage to decrease the level of complexity of the solution such that management tasks can be performed by a person with limited computer network and vendor-specific knowledge.

In order to assist the network administrator, it would also be an advantage to provide a plurality of pre-configured or “canned” network configurations. Thus, for relatively simple network configurations, the administrator would not even have to design the network topology, as long as the available network components matched the canned network configuration.

It would also be an advantage over the prior art to provide a solution where the network configuration can be modified on the fly. The system should also be capable of enabling control of the system, if desired, down to single network port control, or sophisticated enough to manage all of the network ports as determined by network conditions.

It would also be an advantage to provide a plurality of these systems such that they can be coupled together in a large network, be it the Internet, or in a more localized WAN or LAN topology. The system should also enable spare processing capability to be made available for other applications, without degradation of the network functions being performed.

It would also be an advantage to provide third parties with the ability to have greater control of how their plug-in hardware or software operates with the invention by enabling programming of ActiveX modules that enable components to be dragged and dropped in a control and management interface into desired network configurations.

Security of state of the art network devices is also a problem because embedded devices typically utilize a modified version of operating system software. The modified version is typically scaled down so as to include limited features. Therefore, it would be an advantage over the prior art to provide a system that utilizes a complete Operating System that can take advantage of the full range of Operating System's capabilities, including security features.

The background described above generally deals with the problems of multiple IP services being provided on a plurality of different platforms, and how it would be advantageous to provide the services in a single non-vendor specific platform. However, another shortcoming of the prior art is in the structure of the Internet itself. There are many high bandwidth applications that cannot be implemented in a practical manner because of the bottlenecks that cannot be overcome with the traditional tree structure being used today. Therefore, it is the purpose of this specification to describe how a plurality of the Open IP Services Platforms can be configured to enable practical implementation of high bandwidth services.

### SUMMARY OF INVENTION

It is an object of the present invention to provide a network topology that when combined with a plurality of Open IP Services Platforms, enables implementation of high bandwidth applications across a global information network such as the Internet.

It is another object to provide a system that enables multiple network functions to be performed within a single device known as the Open IP Services Platform.

It is another object to provide the system wherein the Open IP Services Platform can perform any combination of the functions of a router, bridge, load balancer, firewall, packet shaper, switch, server, or any other network devices.

It is another object to reduce congestion on the global information network.

It is another object to reduce vulnerability of the global information network to peak loads caused by normal use as well as intentional attacks.

It is another object to reduce latency on the global information network.

It is another object to reduce expenses associated with centralized bandwidth and storage capacity of the global information network.

The present invention is embodied in a switch fabric global information network topology, wherein a switch fabric network matrix provides an Open IP Services Platform at each node thereof, the Open IP Services Platform providing decentralization of network services and a constant trunk size, wherein the switch fabric network matrix eliminates saturation of any communication line, thereby always making bandwidth available, and providing an infinitely scalable network topology.

In a first aspect of the invention, a centralized distribution model of the Internet is abandoned in favor of a switch fabric network matrix.

In a second aspect of the invention, each node of the switch fabric network matrix utilizes at least one Open IP Services Platform to provide all IP services, including high capacity data storage.

In a third aspect of the invention, an overloaded node is able to pass off IP service tasks to any other node in the switch fabric network matrix.

In a fourth aspect of the invention, the switch fabric network matrix is optimized for a high percentage of local network traffic, thereby alleviating the burden on trunk lines, and reducing the need for large network backbones.

In a fifth aspect of the invention, each node in the switch fabric network matrix maintains bandwidth.

These and other objects, features, advantages and alternative aspects of the present invention will become apparent to those skilled in the art from a consideration of the following detailed description taken in combination with the accompanying drawings.

### DESCRIPTION OF THE DRAWINGS

FIG. 1 is a block diagram of a typical network topology of the prior art.

FIG. 2 is a block diagram of an Open IP Services Platform that functions as a building block for a switch fabric network matrix.

FIG. 3 is a block diagram that explains how the Open IP Services Platform 30 incorporates a Level 4 switch router at the bottom level, and a general purpose central processing unit (CPU) 34 at the top level.

FIG. 4 is a block diagram that is provided to give greater detail to the configuration of the Open IP Services Platform.

FIG. 5 is a block diagram of the software architecture in the Open IP Services Platform.

FIG. 6 is a block diagram of a traditional tree structure of a network.

FIG. 7 is a block diagram illustrating the problems that occur when there is a saturated communication line in the traditional tree structure network of FIG. 6.

FIG. 8 is block diagram illustrating the switch fabric network matrix that is made in accordance with the principles of the presently preferred embodiment.

FIG. 9 is a block diagram of an alternative embodiment of the present invention.

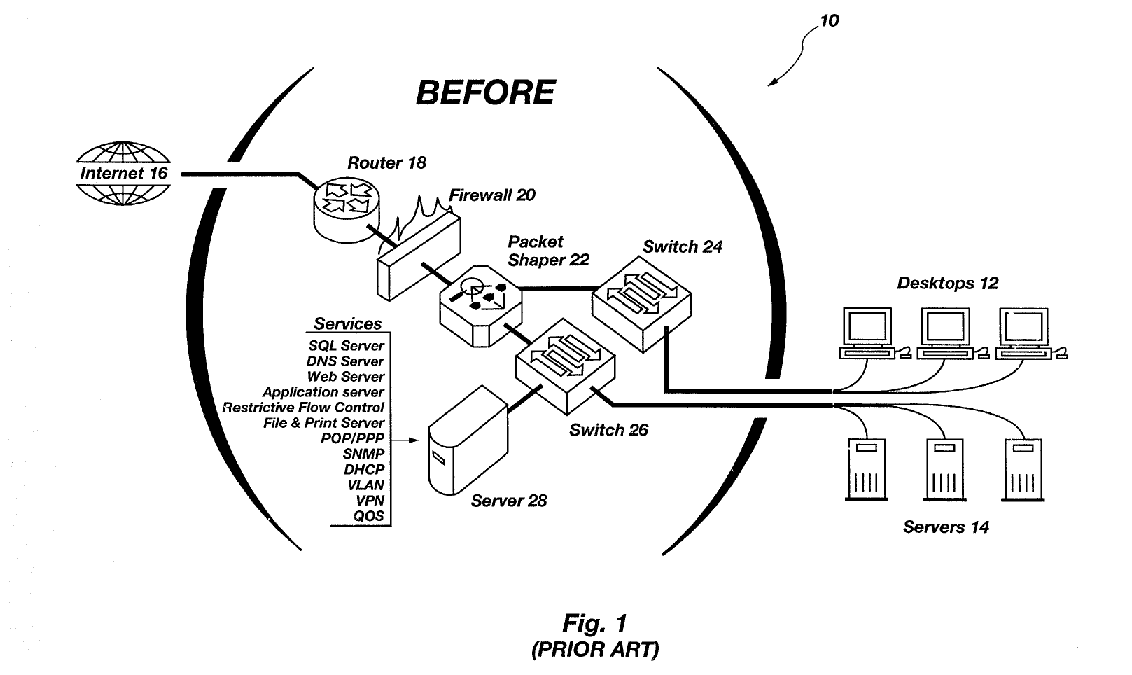

### DETAILED DESCRIPTION

Reference will now be made to the details of the invention in which the various elements of the present invention will be described and discussed so as to enable one skilled in the art to make and use the invention. It is to be understood that the following description is only exemplary of the principles of the present invention, and should not be viewed as narrowing the claims which follow.

The present invention encompasses a range of improvements that by themselves and in combination are novel inventions. The fundamental building block of the invention is a new network topology to be applied to a global information network, such as the Internet, and a new type of network device to be referred to as an Open IP Services Platform.

One purpose of the present invention is to provide a new Internet topology that, in combination with a new type of network switching node device, offers several advantages over the prior art. Another purpose of the present invention is to offer a device that can function as the network switching node device. However, the network switching node device is described in this specification in terms of how it can provide the desired functionality to make the new Internet topology function as described.

This description will first address the network switching node device that enables the new network topology to function. Then, the specific drawbacks of existing Internet topology will be examined. Finally, the new network topology will be examined in combination with the network switching node devices that make the network function as described.

First, it is important to understand that the Open IP Services Platform is capable of functions that are found in no other network device. To understand the advantages of this Open IP Services Platform, it is helpful to name a few network devices, and explain how their functions are all performed by the present invention.

Typical network components include but are not limited to routers, bridges, firewalls, packet shapers, switches, load balancers, and servers. These devices can all be found on a first side of the router, wherein on the second side, the router functions as a gateway to networks such as LAN segments, WANs, and the Internet or other global information networks. The specific topology of these networks on the first side of the router can vary significantly depending upon the needs and functions of the local network segment. Thus, several of the problems that the present invention overcomes include 1) the total number of physical devices that may be required for a network, 2) the number of wires that must be installed between the devices, 3) the time required to configure the devices, 4) the level of knowledge of the person that is installing the devices, 5) an understanding and memory of the specific topology that has been set up, and 6) the ability to reconfigure a topology on-the-fly.

The network switching node device of the present invention is able to overcome these problems for several reasons. First, all of the network devices can be physically disposed within a single network switching node device, or Open IP Services Platform. Obviously, there are many obstacles that must be overcome to do this. For example, the Open IP Services Platform of the present invention is constructed to accept network components from third parties. In other words, it is not a feature of the present invention to provide these network components, rather it is an aspect of the invention to provide a device that can house them in the Open IP Services Platform. Not only can these network components be disposed within the Open IP Services Platform, but more than one type of network component can be housed together. Essentially, all of the network components listed previously, as well as others, can be housed within a single network switching node device of the Open IP Services Platform.

In order to dispose these network components together so that they function, several novel elements of the present invention had to be developed. A first aspect was a system for configuring the interconnections between the network components in the Open IP Services Platform. Consider multiple switches and a packet shaper disposed within the Open IP Services Platform. The packet shaper must be coupled to specific ports of the multiple switches. It is a novel aspect of the invention to provide a software package COREVISTA WEB(™) that provides configuration control by physically interconnecting network devices that are stored within the Open IP Services Platform. Control over network devices in the Open IP Services Platform is provided at what can be considered to be two levels. The first level of control enables the user to make specific port assignments if the system administrator is experienced, while the second level of control takes specific port assignments out of the hands of the administrator, and allows the specific configuration of ports to be left to the configuration software if the system administrator has only a limited understanding of network topology, or does not want to be bothered with control at that level.

It should be mentioned that the software package for configuration and management of the device is simple enough to operate that a network specialist does not have to be brought in to set up the Open IP Services Platform. This aspect of the invention is made possible because the interface provides drag-and-drop configuration, as well as pre-configured loads.

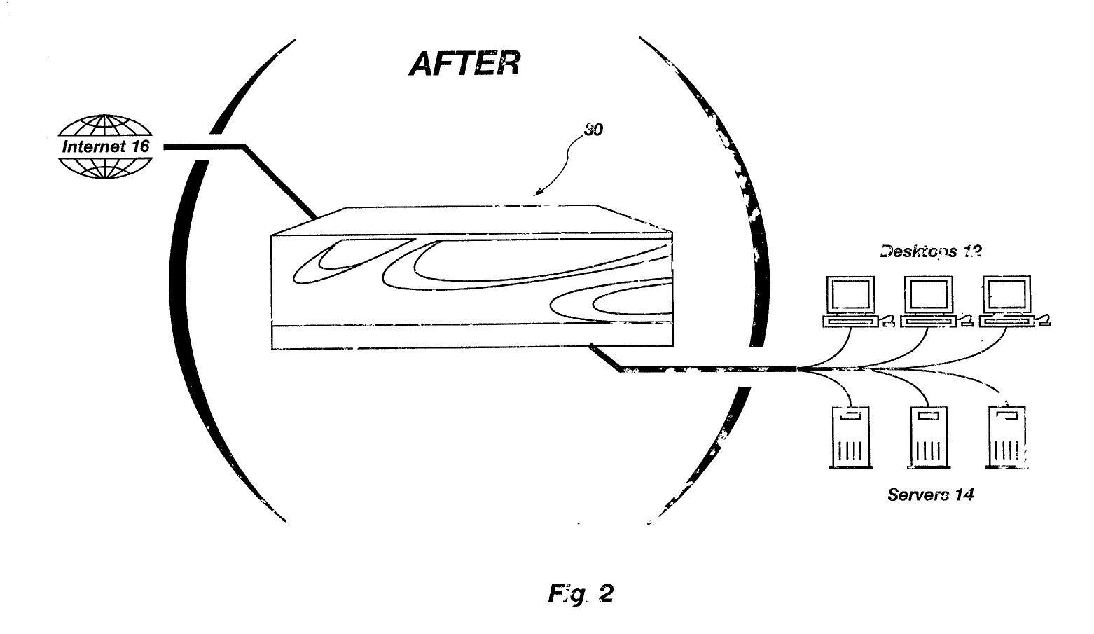

With this brief introduction, a single network switching node device of the invention is shown in FIG. 2. FIG. 2 illustrates that all of the network services provided by individual network components 18, 20, 22, 24, 26, 28 have been replaced by a single Open IP Services Platform 30. It should be remembered that any or all of the functions of the network devices described above can be replaced as desired. Furthermore, it is another aspect of the Open IP Services Platform to include at least one large computer hard drive, or other modifiable mass storage device. It is probably an important aspect of the invention to provide mass storage capabilities in each network switching node device device too thereby increase local network traffic.

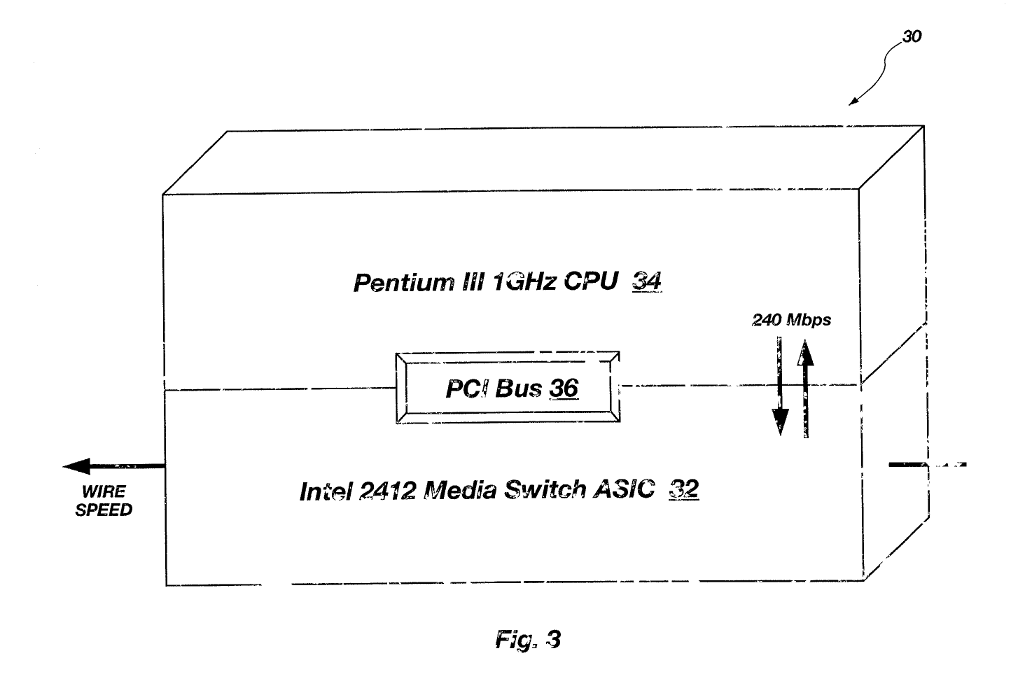

FIG. 3 is a block diagram of the inner structure of a network switching node device or Open IP Services Platform of the present invention. This figure is provided to illustrate that the Open IP Services Platform 30 incorporates a Level 4 switch router 32 at the bottom level, and a general purpose central processing unit (CPU) 34 at the top level. It should be mentioned that while a general purpose CPU is preferred, any type of specialty CPU can be substituted. The reason for preferring a general purpose CPU is that it is going to be more flexible. In other words, the Open IP Services Platform 30 can do more than just function as a unit for consolidating network functions if it is given more processing power, and the ability to run more programs simultaneously. The drawback is that a specialty CPU can be faster. However, given the fact that general purpose CPUs have increased in operation capabilities so rapidly, it is unlikely that the CPU would be a bottleneck to performance for most situations where the Open IP Services Platform is deployed. And for the present invention, versatility is an important feature.

The switch router 32 communicates with the CPU 34 via an internal Peripheral Component Interconnect (PCI) bus 36. Presently, that translates into a communication conduit of 240 Mbps between those components 34, 36. However, the switch router 32 is communicating at wire speed with network components in levels 2-4.

It is noted that it would take an OC-3 connection to the Internet for the input to the Open IP Services Platform 30 to exceed the processing throughput capabilities of the CPU used in the preferred embodiment. The OC-3 type of connection is uncommon to most businesses, and thus the present invention is going to handle almost all connection scenarios without becoming a bottleneck.

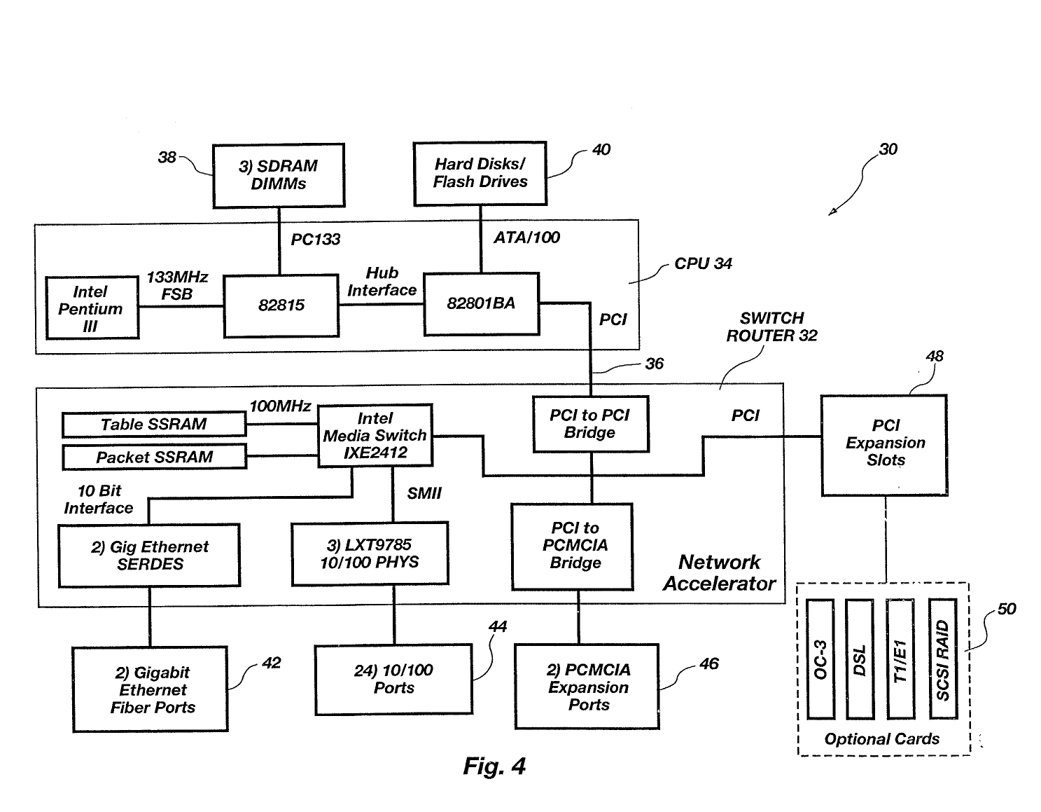

FIG. 4 is a block diagram that is provided to give greater detail to the configuration of the Open IP Services Platform 30. The CPU 34 is preferably a single board computer (SBC) operating with an INTEL(™) chipset. However, any INTEL(™) compatible CPU can be easily substituted, such as a CPU from AMD(™). The preferred microprocessor for the SBC 34 is an INTEL(™) PENTIUM(™) III. However, the software of the Open IP Services Platform can be optimed for other processors as well, such as the Pentium 4 (™).

The SBC 34 communicates with memory in the form of SDRAM DIMMs 38, and possibly an array of hard drives/flash drives 40. The hard drives/flash drives 40 are optional, depending upon the needs of the network or of the network components being incorporated into the Open IP Services Platform 30, as will be explained.

The switch router 32 is shown coupled to the SBC 34 via the PCI bus 36. The switch router 32 has also been labeled as a network accelerator to more fully describe its function. The switch router 32 is shown as providing the port connections to external networks via the Gigabit Ethernet Fiber (GBIC) Ports 42, 10/100 Mbps Ethernet (Base T) Ports 44, PCMCIA Expansion Ports 46, and additional PCI Expansion Slots 48.

The PCI Expansion Slots 48 are designed to receive the hardware of the network function being installed. In other words, a third party network function card is installed in one of the PCI Expansion Slots 48, enabling the Open IP Services Platform 30 to function as a load balancer, a firewall, etc.

It is also noted that optional cards 50 can also be installed into the PCI Expansion Slots 48. These optional cards can include such functions as OC-3, DSL modem, T1/E1 termination, and SCSI RAID. Thus it is seen that the Open IP Services Platform 30 is not fixed in its configuration or its function.

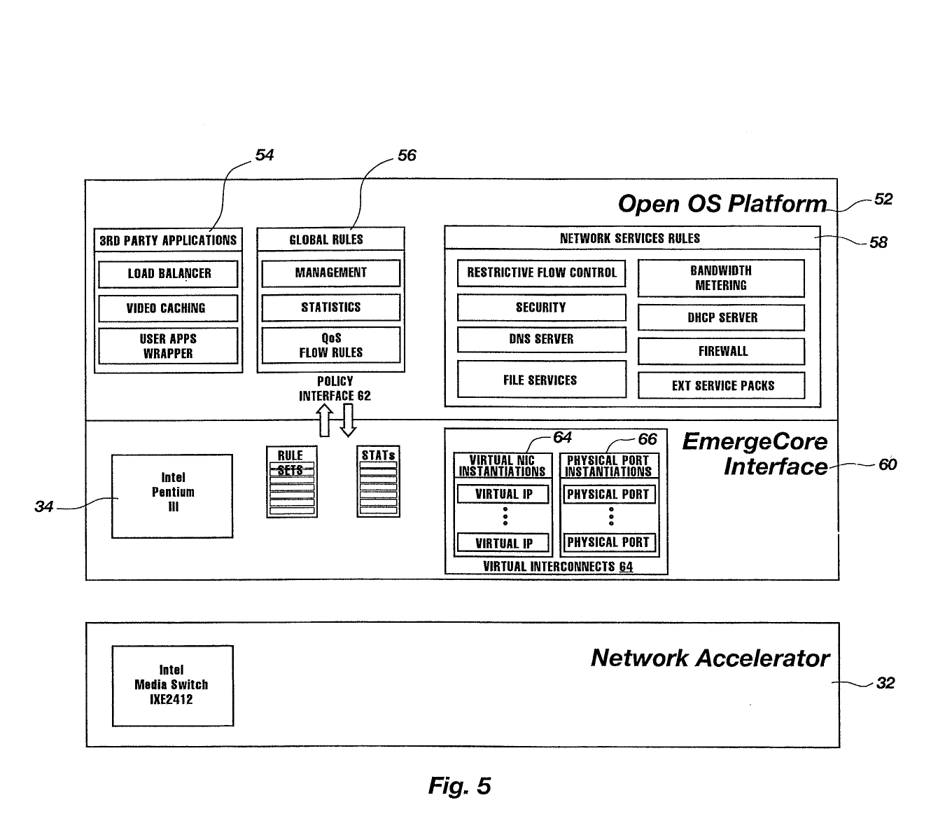

FIG. 5 is a block diagram of the software architecture of the present invention. The Operating System 52 is preferably one that has an open architecture. This selection of an open architecture OS was made so that the system administrator is given the ability to modify the operating system itself, if necessary, in order to obtain the desired functionality of the invention that can only come through customization, without having to depend on others to provide the desired capabilities.

Another advantage of utilizing an open architecture OS is that some users will want to drop their own software into the Open IP Services Platform 30. Unfortunately, this flexibility also enables users to write code that can potentially interfere with the other functions in the Open IP Services Platform 30. Advantageously, utilizing the complete OS provides memory management capabilities that prevents third party software from jeopardizing the operation of any other network functions taking place. For example, protected memory can prevent flawed software from bringing down the Open IP Services Platform 30.

The Open IP Services Platform 30 is also operated by a multi-tasking operation system. In the presently preferred embodiment, a stable and secure OS is desired. The Open IP Services Platform 30 is currently operated using FreeBSD or Linux. However, other operating systems such as WINDOWS XP(™) cane be used with modifications to the management software of the Open IP Services Platform 30. It is also important to understand that the OS operation within the Open IP Services Platform 30 is not what is typically referred to as an embedded OS. An embedded OS is often a smaller and less capable version of the complete OS. The present invention utilizes the complete OS so that all capabilities of the OS are available. These capabilities include the all-important security features.

The Operating System 52 executes third party applications 54, with the global rules 56 including management, statistics, and Quality of Service flow rules, and network services rules 58. Network service rules 58 include restrictive flow control, security, a DNS server, file services, bandwidth metering, a DHCP server, a firewall, and external service packs.

The Operating System 52 communicates with the interface 60 of the SBC 34. This communication is controlled via policy interface 62. Virtual interconnects 64 handle the translation within the SBC 34 of mapping virtual NIC instantiations 66 to physical port instantiations 66.

Presently, the network switching node devices come in two different system configurations, the REACTOR(™) and the REACTORPRO(™). There are several common features in these products including: two Gigabit GBIC Ports 42, twenty four 10/100 (Base T) Ports 44, a single 733 MHz PENTIUM(™) III CPU 34 that is ungradable, 32 MB of RAM and 32 MB of Flash RAM 38, both ungradable, two USB ports, one serial port that is optional, and two PC card slots 46, type 2. The devices are different in that there are two PCI bus slots, and an optional hard drive on the REACTOR(™). In contrast, the REACTORPRO(™) includes four PCI bus slots, and comes with two PAID bays for up to 6 hard drives, and a redundant power supply. Both systems are configurable via local PC, serial port, modem, or via a network connection. More control is possible, however, using a configuration program that operates in the WINDOWS(™) environment.

It is observed that presently both systems run FreeBSD 4.2 and Linux Kernel 2.2.17 (RedHat 6.2 or 7.0, Mandrake 6.2) Operating Systems. However, a PC running any Operating System can communicate with the Open IP Services Platform 30 via Telnet or a command line interface. But the software configuration tool, COREVISTA WEB(™), is currently a WINDOWS(™) application.

Other important statistics of the systems are that the address table size is 16K IP and 8K IPX addresses with no per port limits, and more available via aging.

The systems also include an RS-232 console port that supports remote monitoring and diagnostics via a DB-9 (DTE) connector. Pre-set configurations include, but are not limited to, internal and external T1, DSL modem, analog modem, and others. A store-and-forward forwarding mode is available. Filtering modes are destination-based, multicast address-based, or port based. 1K virtual LAN support is also provided.

Upgrades to the Open IP Services Platform 30 are also available using the FTP protocol via Flash PROM. Additional features include port priority, port aggregation (multi-link), port mirroring for RMON probes, and link aggregation and redundancy where up to 8 ports can be configured as a single 800 Mbit link.

When considering how the present invention is different from the state of the art, the present invention can also hook the networking functions into a server to make network functions more seamless. In other words, instead of just operating as a Network Interface Card (NIC) tied into a switch or router, the present invention provides full control over the switch/router functions. This approach is different from the state of the art because no one has previously tried to provide this type of interface that enables a third party to load their own components into a box that is providing some type of network function. In fact, this approach is antithetical to the business model of any other network function provider. For it is the desire of suppliers of network functions that the user not try to add hardware or software components of a third party into their own box. It will potentially decrease their own revenue stream. Obviously, this type of approach severely limits trying to build a “best of class” network if a user can only install certain brands of products when the overiding feature of interoperability is a must.

Thus, the present invention performs the unique function of being an integrator of network products that have previously required separate boxes or isolated operation in order to function. Advantageously, the present invention does not have to try and provide any of the network functions themselves, but instead provides a box that enables network cards performing all manner of functions to be disposed therein, while providing the hardware and software to make interconnections between the different network cards. Thus, even though the present invention does provide switch/router capabilities, even these functions can be replaced or enhanced by the addition a third party switch or router card.

One of the novel aspects of the invention is that because the present invention is not trying to duplicate the functions of a proprietary firewall, call it Firewall A, there are no licensing fees to be paid because Firewall A is purchased and put into the Open IP Services Platform 30 as a separate add-in component. The Open IP Services Platform 30 thus provides all of the functionality of Firewall A because it includes Firewall A inside it. Likewise, Load Balancer B is manufactured by a different company, is purchased, and disposed within the Open IP Services Platform 30 next to Firewall A. Firewall A and Load Balancer B now provide all of their functionality in a single box. All interconnections between them are provide by the present invention, and are configurable down to a port-by-port basis.

Another novel aspect of the invention is that it prevents exclusivity of function. Suppose that the manufacturer of Firewall A enters into an exclusive contract such that it is no longer available for use in the Open IP Services Platform 30. Advantageously, Firewall A is removed and Firewall B is put in its slot. After loading Firewall B's drivers, it is likely that no other configuration of Firewall B will be required. The firewall functions will operate as before.

It is another aspect of the invention that most network functions can be added into the Open IP Services Platform 30 without modification. The only requirement is that the driver for the network function must be provided for the OS that is running on the Open IP Services Platform 30.

One aspect of the Open IP Services Platform 30 that is of particular importance to the present invention is that a plurality of the Open IP Services Platforms 30 can communicate with each other at wire speed. This is advantageous when, for example, a particular function is not being performed fast enough in one particular unit. Just one function can be rerouted at wire speed to another Open IP Services Platform 30.

Consider an Open IP Services Platform 30 that is performing the functions of a server that is providing FTP, web services, mail services, etc. It is possible to assign any of the services to different servers (Open IP Services Platforms 30), at wire speed, to keep performance at a desired level. The present invention can also reconfigure the Open IP Services Platform 30 on the fly such that when certain performance bottlenecks are being reached, the Open IP Services Platform 30 will reassign functions as previously defined by the administrator.

Another feature of the present invention is that both configurations of the Open IP Services Platform 30 provide keyboard, mouse, and monitor ports. Thus, the Open IP Services Platform 30 is capable of operating as a full-fledged server that a developer can work on directly.

It is observed that the physical dimensions of the Open IP Services Platform 30 are also industry standard for use in data centers and other facilities that use rack mounted equipment. The dimensions vary from a 1U-high to a 3U-high unit that are rack-mountable.

Another novel aspect of the invention that increases versatility is the type of environments in which the Open IP Services Platform 30 can operate. Small businesses are often stashing network components into closets or other tight spaces. This closed environment typically runs hotter than a room with its own thermostat. Accordingly, the Open IP Services Platform 30 would normally run at a higher than optimal temperature. Another aspect of the invention is to provide a solid state refrigeration unit. This aspect is especially important when considering the commercial and industrial locations where the Open IP Services Platform 30 will be used. This is also more important for the REACTORPRO(™) model that includes hard drives. Hard drives are especially vulnerable to high operating temperatures. The refrigeration unit can be disposed just on the hard drives themselves.

With these features in mind, it is useful to consider the manner in which the present invention utilizes them to achieve novel advantages, while observing that the advantages are available to all of the targeted core markets of SPs, LECs and Enterprises. First, the invention provides a consolidated equipment solution. Managing a wide array of single-function, multi-vendor network devices creates high installation and management costs. The present invention consolidates the many functions performed by the individual network devices. The equipment consolidation can be partial or total, with a single device replacing entire racks of physical equipment. Consolidation of network functions solves a critical long-term build-out problem in Enterprise IT rooms, SP data centers, and in LEC central offices where equipment proliferation often overwhelms available power, air conditioning or physical space limitations. Consolidated equipment means that there are fewer interconnections, fewer cables, and fewer moving parts to fail, resulting in increased uptime and reduced ongoing support costs.

Consolidated network equipment greatly simplifies installation and ongoing maintenance. The present invention includes an elegant, intuitive, centralized management application, COREVISTA WEB(™), that enables installation in less than 15 minutes. Thus, the administrator can deploy units without needing to complete multiple, vendor-specific, certified training programs as will be explained. The present invention even offers self-configuring features on base units.

The flexible allocation of network resources is made possible because software is used to make all connections between network devices installed in the present invention. Any single or combination of virtual or physical ports can be instantly reassigned new IP services on a port-by-port basis. This enables the administrator to reconfigure IP services as needs change, and without taking down any part of the network. This aspect is especially critical to large Enterprises, and almost any SP and LEC.

One of the greatest advantages of the present invention is the use of open IP standards. Proprietary technologies are often initially attractive because lower costs can be achieved for a specific function. Disadvantageously, however, proprietary technologies often limit selection of complementary equipment, leaving the network function isolated and unexpandable. Additionally, proprietary equipment can preclude the use of certain IP services completely, and can require an administrator to provide specialized training for staff. Thus, hidden costs add up and quickly surpass any initial savings.

The present invention delivers a truly open architecture communications platform specifically designed to enable rapid deployment of “best in class” applications and value-added services for mission-critical communications, while preserving existing infrastructure. The present invention also enables the administrator to offer any IP service through the Enterprise, SP or LEC.

Configuring the Open IP Services Platform 30 can be performed in various ways. To drag and drop icons representing the network components requires that the administrator access the Open IP Services Platform using the COREVISTA WEB(™) configuration program. It is envisioned that a different version will enable the administrator to configure what is already loaded in the Open IP Services Platform 30, but not to design the layout. In other words, it enables the administrator to configure what is already loaded, but not change the layout.

When performing configuration over a network, it is noted that SSH is provided for a secure and encrypted configuration session.

One useful feature is that the configuration can be stored on and loaded from a PC card. Thus, if an SP or LEC needs twenty identical Open IP Services Platforms 30, only one has to be manually configured using the COREVISTA WEB(™) configuration program. The configuration is then stored on a PC card that can be duplicated. The administrator then only has to insert the PC card into a non-configured Open IP Services Platform 30, and load the configuration.

Both the REACTOR(™) and the REACTORPRO(™) Open IP Services Platforms include a host of standard software applications right out of the box. These software applications include an APACHE(™) web server, SQL(™)-based database management, various drivers and interface for the ports and other hardware, DHCP, IPB4 router, network access translation (NAT), a restrictive flow packet shaper, SNMP, point to point protocol (PPP), a virtual private network (VPN), a virtual LAN (VLAN), SSH tunneling. Some Open IP Services Platforms can also include a SAMBA server, DNS, a POP mail server, and full software or hardware RAID functionality.

The present invention also provides a standardized interface to all of the network cards that can be loaded. This interface is SQL-based to enable full control over access to the network functions. It is also a function of the invention to provide ActiveX modules for each network function that is being added. The power of this feature is that, for example, the ActiveX module can be input to a spreadsheet. As the network is operating, the spreadsheet is displaying all of the statistics of that network function in realtime.

One of the advantages of the present invention that may not yet be apparent is that it includes a central point of configuration control. Each network card has an associated database and ActiveX component. Thus, two firewalls can be configured in exactly the same way. Obviously, each firewall card requires its own unique driver and instruction set because they are probably proprietary systems. Surprisingly, both of the firewall cards can be controlled using the identical ActiveX component and the same database. The present invention is able to provide a centralized, standard interface program that performs the translation between the database and the firewall cards themselves.

It was stated previously that the present invention provides allocation of network resources at the port, protocol, and IP address level. In other words, it is possible to control and thus sell IP services on a port-by-port basis. It is useful to examine several examples of how this works.

Consider an office building with four tenants, A, B, C and D. In a packet shaper that comes with the REACTOR(™), each of the tenants can be allocated Internet access by a rule set, trigger point, or manually. Rule sets are used to allocate resources. For example, the tenants can share a T1 line equally, where each tenant is restricted to 300 kb of bandwidth. A trigger point is used to activate particular rule sets, depending upon the conditions. Finally, it is possible to manually override the rule sets and trigger points.

A first example is when none of the tenants are restricted to the amount of bandwidth that they can use. Therefore, tenant A may use 800 kb of bandwidth without interfering with the other tenants. Then, tenants B, C, and D all need 200 kb of bandwidth. At this point, the bandwidth of the T1 is exceeded. A trigger point can be set so that when bandwidth demand exceeds the maximum available bandwidth, the tenants are restricted. The rule set that is activated can divide all the bandwidth equally, or still favor the heaviest bandwidth user while reducing the bandwidth to that user.

Bandwidth can also be allocated according to the type of activity that is being performed. Thus, activity can be restricted based on protocol, or the type of activity that is occurring. Thus, all tenants can be given unrestricted flow control on e-mail, but restricted flow on web browsing or FTP.

It was mentioned that flow control can be managed down to a single port. For example, there can be three ports, each port having a unique firewall and flow control configuration.

Another feature of the present invention when rules and trigger points are useful is when access is suddenly restricted to the Open IP Services Platform 30 itself. For example, a cable in the ground is cut by some construction activity. The Open IP Services Platform 30 can reconfigure itself based on the total available bandwidth that it sees. Thus, when a T1 line is cut, and the dial-up access becomes the only way to access the Internet, all users may be severely restricted, and yet enable vital services such as email. However, access to web servers behind the Open IP Services Platform 30 from the outside may have to be eliminated to ensure email access.

Not only can access to outside networks be dynamically allocated, but it is also possible to perform access metering. Thus, if a tenant desires to be charged only for actual use of access to an outside network, this can be done.

It is important to realize that the scenarios described above are available only because all of the network functions are disposed within a single network switching node device that can reconfigure itself on the fly.

The specification above is specifically addressed to the novel aspects of the hardware and software integration of third party network cards. However, it is mentioned that COREVISTA WEB(™) is also considered a novel aspect of the invention, as is the unique database structure that enables the configuration software to function with and configure all the third party network cards that are disposed within the Open IP Services Platform 30. However, all of the functionality of these other novel aspects of the invention are not required for the invention to function. What is important is that a common SQL database structure be provided that enables each network function to be controlled thereby. Regarding the configuration software, it is only necessary that each network function be controlled by an ActiveX module that is linked to an SQL database. Thus, a consistent interface to the actual network cards is provided. Furthermore, third parties can develop and deliver their own ActiveX module for their network component.

By assigning each ActiveX module to its own SQL database, each network component is able to have its own password to its functionality. Therefore, an administrator can have a unique password for each network component, thereby allowing access to specific modules without compromising the entire network configuration.

The other advantage of SQL databases is that each module can be controlled by a set of rules. These rules can be manually triggered, or automatically triggered by an event. The events can be time-based or triggered by network conditions. Likewise, bandwidth usage can be restricted when the demands outstrip the available supply. These events can even trigger a call for help to a system administrator or to another designated party.

This flexibility in control of the aspects of the Open IP Services Platform enable unprecedented opportunities. For example, a business can provide Internet access to any other business in a building, thus operating as a mini-Internet Service Provider (ISP). Bandwidth can be dolled out in any desired increments to users. The bandwidth can even be controlled down to the port on a switch.

The specification above has explained the advantageous functionality provided in the Open IP Services Platform 30. However, a critical aspect of this invention is the ability to utilize a plurality of Open IP Services Platforms 30 in a coordinated manner, and in a new network topology.

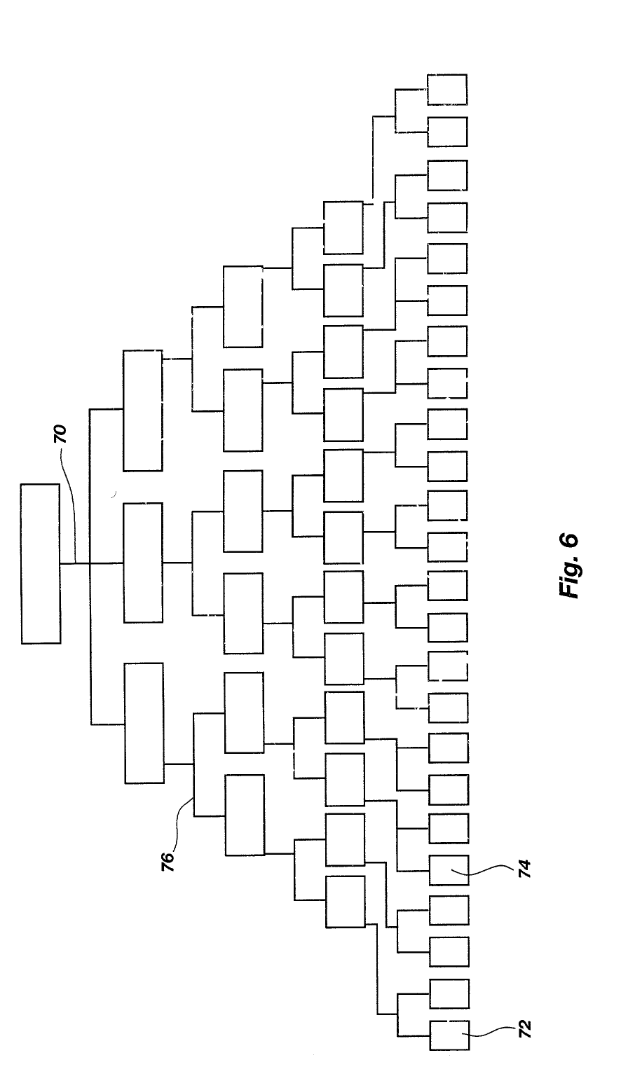

The traditional tree structure of many networks, including the Internet, is shown in FIG. 6. FIG. 6 is a block diagram illustrating the functional design of the traditional tree network architecture. This type of network is referred to as a centralized distribution model. The centralized distribution model is like the branches of an up-side down tree, the branches spreading out below, and coming together to a single trunk 70 at the top. The centralized distribution model inherently suffers from scalability issues.

Consider the trunk 70 to be a trunk line to the Internet. Every node below the trunk line 70 must access the Internet by passing data through it. Furthermore, if a node 72 wants to communicate with a node 74, the communication must pass through branch line 76. It should be easy to see from FIG. 6 that local network traffic will often travel the same data paths as nodes that are communicating with the trunk line 70 and the Internet. The result can be saturation of communication lines.

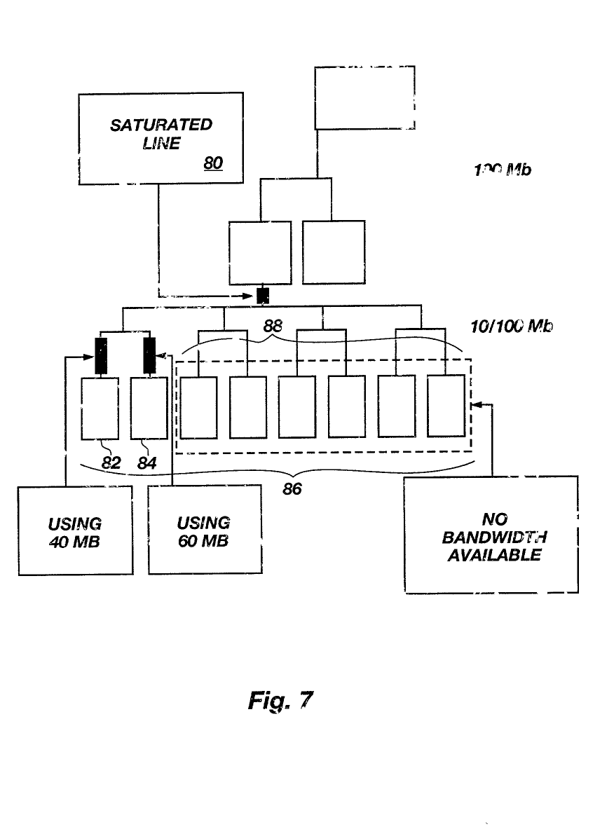

FIG. 7 is provided as an illustration of the problems that occur when there is a saturated communication line 80. Consider two nodes 82 and 84. The first node 82 is utilizing 40 Megabytes of bandwidth, and the second node 82 is utilizing 60 Megabytes of bandwidth. On a 10/100 MB per second network line, that means that nodes 82 and 84 have taken up all the available bandwidth for all the nodes 86 that must use communication line 80 to transfer data. No bandwidth is available at all for the remaining nodes 88. Accordingly saturation or network congestion by only a few nodes can eliminate access for many nodes.

An illustration of one such problem with the tree network architecture is that the network is vulnerable to common network hacking problems such as denial of service (DOS) attacks. Unfortunately, DOS attacks are a part of the Internet that are not likely to go away anytime soon. Even well-protected and well-funded sites can be brought down by a hacker of limited experience by flooding a node with IP service requests. The present invention would inherently resist such attacks by providing many more pathways to any node in a switch fabric network matrix. Furthermore, even if a single node is successfully flooded, all adjacent nodes should not be affected because there is no single communication line that would become saturated. Thus, an Internet site that is mirrored on other nodes is more likely to remain operational, at least on a limited basis.

Another scalability issue concerns mass storage. Mass storage is still expensive when dealing in large quantities. For example, a terabyte capacity mass storage system can cost millions of dollars. Unfortunately, the centralized distribution model generally requires that mass storage be disposed at a single node.

Another issue related to mass storage is having a service that many nodes desire to access. For example, consider video-on-demand. Under the present centralized distribution model, video-on-demand is not a service that can be offered.

Mass storage and video-on-demand services are related in that saturation of communications lines is almost certain to occur at peak loads. The present invention overcomes both of these problems. An important principle in the network topology of the present invention is to make as much traffic as local as possible. To do this, it is necessary to utilize distributed mass storage. In other words, instead of providing massive storage at a single node, less storage is provided at a much greater number of nodes.

Consider the example of video-on-demand. This application enables a user to access a video on the Internet, and view the video as a data stream, or streaming video. Video requires large amounts of storage space, but it is no longer uncommon for a single hard drive to be to store several videos in digital format.

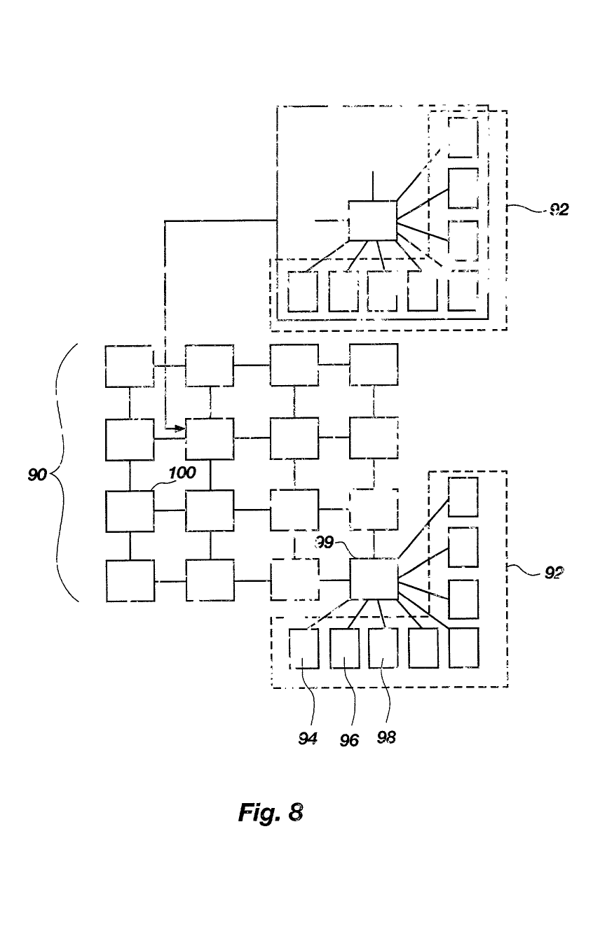

FIG. 8 is provided as an illustration of a network topology as taught by the present invention. The figure shows sixteen network switching node devices 90, each of which is an Open IP Services Platform. Each of the network switching node devices 90 includes at least one hard drive which is capable of storing, for example, the current top five video rentals in digital format, ready for streaming. In FIG. 8, two of the network switching node devices 90 are expanded to show that they are accessed by a plurality of user nodes 92. These user nodes 92 will be considered to be homes. They could also be a mixture of businesses and residential customers. Consider user one 94, user two 96 and user three 98. Each of these users desires to view video one. Video one is stored on the network switching node device 99.

The first immediate advantage of the present invention is that when each user 94, 96, 98 requests to view video one, the immediately local network switching node device 99 is able to provide this service, without having to request the service from further out on the switch fabric network matrix.

However, suppose that user two 96 wants to see video two which is an older video. Older videos are not being stored at each of the network switching node devices 90. Instead, they are being stored at just a few of the local network switching node devices because the demand is going to be smaller. Thus, network switching node device 100 might be used to store video rentals 6 through 10 for all the local network switching node devices 90. User two 96 will access network switching node device 100 by any available communication path. There are between two and four communication paths to each node 90 in FIG. 8.

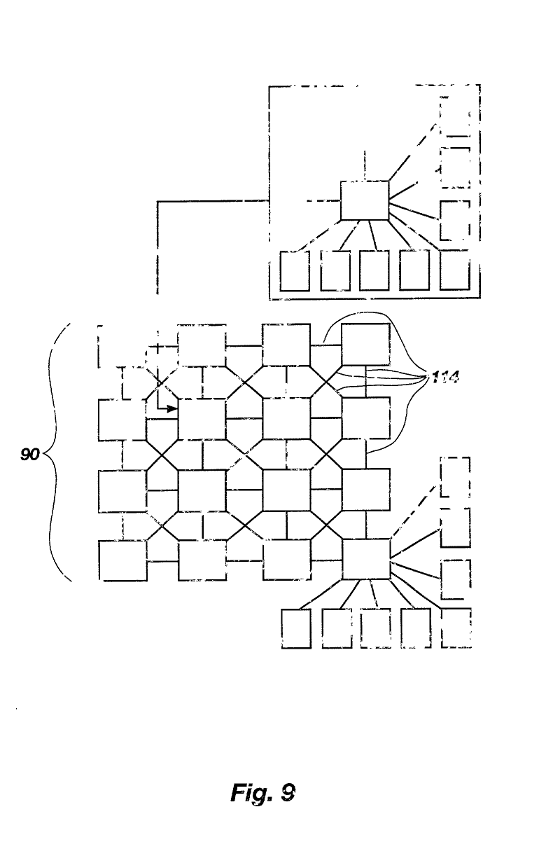

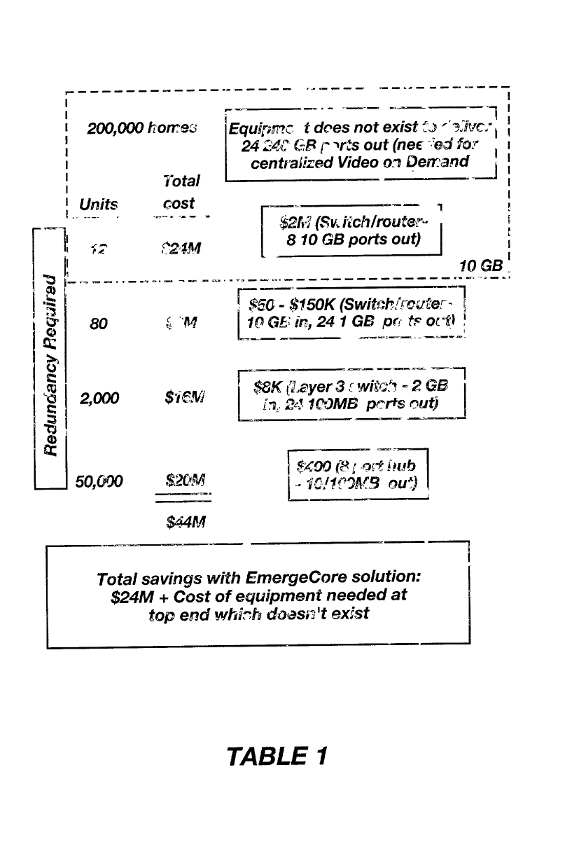

FIG. 9 shows that the switch fabric network matrix shown in FIG. 8 can be modified to provide more communication paths between the network switching node devices 90. For example, in an alternative embodiment, the switch fabric network matrix provides diagonal communication paths between network switching node devices 90. It is important to remember that the switch fabric network matrix is illustrative of a logical configuration. Thus, what is important is that the communication paths 114 between each of the network switching node devices 90 be a direct connection as shown.

By storing a large part of heavily demanded applications, videos, etc near the end users where it is part of local traffic to access, the switch fabric network matrix alleviates network congestion on a trunk line. And in a bandwidth intensive application such as video-on-demand, saturation is more likely a reality, and not just a probability in the centralized distribution model. In contrast, the switch fabric network matrix will make high bandwidth demanding applications as close as a local network switching node device.

However, it is not only video rentals for high bandwidth applications such as video-on-demand that can be stored locally. It is also an aspect of the invention to cache commonly accessed web sites in local network switching node devices. A single local node can even perform the task of obtaining updates of web sites. Then, the local node can inform other local network switching node devices that the web site data can be downloaded from its mass storage device, instead of each local network switching node device retrieving the same data through a trunk line. This action substantially decreases access through the trunk line.

Because the need for high volume traffic through a trunk line to the Internet or other networks is decreased, another advantage of the switch fabric network matrix is to reduce the need for trunk lines having a large bandwidth. Thus, the total number and the size of the trunk lines can be kept to a minimum, or existing trunk lines can have their useful lifespan extended.

Another advantage of the present invention is easily providing the capability of expansion. Consider a local network comprised of 100 users. As the number of users on a local network grows, capacity of the local network is increased by adding local network switching node devices to the switch fabric network matrix. Accordingly, each communication line between local network switching node devices maintains the same bandwidth, and is not progressively increasing.

Another aspect of the invention is the ability to handle guaranteed access. This scenario can be described by considering the traditional tree structure shown in FIG. 7. Utilizing T1 and fractional T1 configurations often provide telephone service, as well as Internet access. Disadvantageously, the traditional tree structure handles quality of service from the trunk to the roots. This is backwards because of the previously described congestion and saturation problems. Saturation will occur at the roots of the tree. The remaining nodes 86 do not have any bandwidth available to them for accessing the trunk line 70.

The switch fabric network matrix shown in FIG. 8 solves the problem of being cut-off from all access to a trunk line. The present invention reserves bandwidth for telephone services at the port level of each Open IP Services Platform, or network switching node device in the switch fabric network matrix. This reservation of bandwidth is made from the outermost edges of the switch fabric network matrix, and on up.

Another advantage of the present invention is illustrated as Table 1. Table 1 is a cost analysis of providing broadband services using the state of the art centralized distribution network as currently implemented, as compared to utilizing the switch fabric network matrix of the present invention. The costs describe delivering the services for video-on-demand to 200,000 homes. Essentially, the total savings are $24 Million dollars utilizing the switch fabric network matrix of the present invention.

It is to be understood that the above-described arrangements are only illustrative of the application of the principles of the present invention. Numerous modifications and alternative arrangements may be devised by those skilled in the art without departing from the spirit and scope of the present invention. The appended claims are intended to cover such modifications and arrangements.

What is claimed is:

1. A method for creating a local network topology that decreases congestion on trunk lines between the local network structure and a global information network, said method comprising the steps of:
1) providing a local switch fabric network matrix as the local network topology, wherein the switch fabric network matrix is comprised of a plurality of network switching node devices; and
2) providing a trunk line that is in communication with the switch fabric network matrix and the global information network, enabling transfer of data and voice communication therebetween.

2. The method as defined in claim 1 wherein the step of providing the plurality of network switching node devices further comprises the step of coupling at least one end user to one of the plurality of network switching node devices.

3. The method as defined in claim 2 wherein the method further comprises the step of providing at least one mass storage device for each of the plurality of network switching node devices, thereby enabling each network switching node device to cache data that can be stored on the global information network.

4. The method as defined in claim 3 wherein the method further comprises the step of enabling an end user to access data from one of the plurality of network switching node devices whenever the data is being stored within the local switch fabric network matrix.

5. The method as defined in claim 4 wherein the method further comprises the steps of:
1) enabling only one of the plurality of network switching node devices to download data from the global information network when the data is desired; and
2) enabling the network switching node device that downloaded the data to share the data with any other network switching node device that desires to cache said data on its own mass storage device.

6. The method as defined in claim 1 wherein the method further comprises the step of increasing local traffic within the local switch fabric network matrix to thereby reduce traffic on the trunk line to the global information network.

7. The method as defined in claim 1 where in the method further comprises the step of reducing congestion on the trunk line to the global information network by:
1) caching data within the plurality of network switching node devices that is also available on the global information network;
2) coupling at least one end user to one of the plurality of network switching node devices; and
3) enabling the at least one end user to access the cached data stored within the plurality of network switching node devices instead of accessing the global information network.

8. The method as defined in claim 5 wherein the method further comprises the step of providing a plurality of Open IP Services Platforms to function as the plurality of network switching node devices.

9. The method as defined in claim 8 wherein the method further comprises integrating the functions of at least two network services in the Open IP Services Platform.

10. The method as defined in claim 9 wherein the method for integrating the functions of at least two network services in an Open IP Services Platform that provides access to a network, said method comprising the steps of:
1) providing a single board computer running an open architecture Operation System, at least two bus connectors coupled to the single board computer, and used for receiving cards that perform network functions, a switch/router board coupled to the single board computer, and a plurality of network ports coupled to the switch/router board; and
2) configuring interconnections between the at least two bus connectors, the switch/router board, and the single board computer by utilizing configuration software that directs a plurality of switches to make physical interconnections within the Open IP Services Platform.

11. The method as defined in claim 10 wherein the method further comprises the step of enabling the Open IP Services Platform to determine a desirable network topology within the Open IP Services Platform for the at least two network functions being performed.

12. The method as defined in claim 11 wherein the method further comprises the step of enabling an administrator to utilize the configuration software to configure individual ports of the Open IP Services Platform.

13. The method as defined in claim 12 wherein the configuration software is able to configure the individual ports of the Open IP Services Platform by selecting a configuration scheme from the group of configuration schemes comprising bandwidth usage, rule sets, trigger points, IP services being performed, and protocol usage.

14. The method as defined in claim 13 wherein the configuration software enables on the fly configuration of the Open IP Services Platform, wherein the Open IP Services Platform is not rebooted in order to effect desired changes in interconnections.

15. The method as defined in claim 14 wherein the method further comprises the step of enabling a plurality of different network devices to be coupled to the at least two bus connectors, wherein the plurality of different network devices are selected from the group of network devices comprising routers, switches, load balancers, bridges, firewalls, packet shapers, and servers.

16. The method as defined in claim 15 wherein the method further comprises the step of enabling network devices from any vendor to be included in the Open IP Services Platform, wherein memory management prevents any one of the network devices from interfering with operation of any other network device.

17. The method as defined in claim 16 wherein the method further comprises the step of enabling any vendor of the network devices to provide a software module that is utilized by the configuration software to represent and control operation of a network device.

18. The method as defined in claim 17 wherein the method further comprises the step of providing the Operating System that includes all components of a complete version, thereby including all security and memory management features.

19. The method as defined in claim 18 wherein the method further comprises the step of modifying or making additions to the Operating System in order to enable a network device to operate within the Open IP Services Platform.

20. The method as defined in claim 19 wherein the method further comprises the step of reducing the time required to configure the network topology, wherein the configuration software provides a graphical user interface that enables an administrator to drag and drop icons representing the network devices into the desired network topology.

21. The method as defined in claim 20 wherein the method further comprises the steps of:
1) providing a plurality of pre-configured network topologies that are stored in memory;
2) selecting of the pre-configured network topologies; and
3) instruction the Open IP Services Platform to implement the network topology defined in the pre-configured network topology utilizing network devices installed in the Open IP Services Platform.

22. The method as defined in claim 20 wherein the method further comprises the step of reducing networking knowledge requirements of the administrator, to thereby facilitate rapid and easy deployment of the network topology.

23. The method as defined in claim 22 wherein the method further comprises the step of enabling operation of the Open IP Services Platform in harsh environments that would otherwise preclude operation of the Open IP Services Platform by providing localized cooling for specific temperature sensitive components.

24. The method as defined in claim 9 wherein the method for providing an Open IP Services Platform is capable of performing various network functions according to the specific network components that are disposed therein, and according to a network topology selected for those network components, said method comprising the steps of:
1) providing a single board computer running an open architecture Operation System, at least two bus connectors coupled to the single board computer, and used for receiving cards that perform network functions, a switch/router board coupled to the single board computer, and a plurality of network ports coupled to the switch/router board;
2) coupling a first set of network devices to the at least two connector buses; and
3) configuring interconnections between the first set of network devices, the switch/router board, and the single board computer to thereby define a first network function and a first network topology for the Open IP Services Platform.

25. The method as defined in claim 24 wherein the method further comprises the steps of reconfiguring through configuration software the interconnections between the first set of network devices, the switch/router board, and the single board computer to thereby define a second network function and a second network topology for the Open IP Services Platform, without having to change the first set of network devices.

26. The method as defined in claim 25 wherein the method further comprises the steps of:
1) removing the first set of network devices from the Open IP Services Platform;
2) coupling a second set of network devices to the at least two connector buses; and
3) configuring interconnections between the second set of network devices, the switch/router board, and the single board computer to thereby define a third network function and a third network topology for the Open IP Services Platform.

27. A local network topology that decreases congestion on trunk lines between the local network structure and a global information network, said system comprising:
a local switch fabric network matrix as the local network topology, wherein the switch fabric network matrix is comprised of a plurality of network switching node devices; and
a connection from the local switch fabric network matrix to a trunk line, wherein the trunk line is in communication with the switch fabric network matrix and the global information network, thereby enabling transfer of data and voice communication therebetween.

28. The system as defined in claim 27 wherein the system further comprises at least one end user coupled to one of the plurality of network switching node devices.

29. The system as defined in claim 28 wherein the system further comprises at least one mass storage device associated with each of the plurality of network switching node devices, thereby enabling each network switching node device to cache data that can be stored on the global information network.

30. The system as defined in claim 29 wherein the system further comprises a plurality of Open IP Services Platforms to function as the plurality of network switching node devices.

31. The system as defined in claim 30 wherein each of the plurality of Open IP Services Platforms further comprises
a single board computer (SBC), including memory;
an open architecture Operating System (OS) stored in the memory;
at least two bus connectors for receiving cards that perform network functions, wherein the at least two bus connectors are coupled to the SBC;
a switch/router board coupled to the single board computer;
a plurality of network ports, wherein the plurality of network ports are coupled on a first side to the switch/router board, and provide a connection to a network on a second side thereof; and
configuration software for controlling interconnections between the at least two bus connectors, the switch/router board, and the SBC.

32. The system as defined in claim 31 wherein the open architecture Operating System is selected from the group of Operating Systems comprised of FreeBSD and Linux.

33. The system as defined in claim 32 wherein the at least two bus connectors further comprise peripheral component interconnect (PCI) bus connectors.

34. The system as defined in claim 33 wherein the switch/router board is further comprised of:
a PCI to PCI bus bridge;
a PCI to PCMCIA bus bridge;
at least one random access memory module; and
a media switch for performing switch and router function.

35. The system as defined in claim 34 wherein the plurality of network ports further comprises:
at least two gigabit ethernet ports;
at least twelve 10/100 ethernet ports; and
at least two PCMCIA type 2 expansion ports.

36. The system as defined in claim 35 wherein the plurality of network ports further comprises at least one universal serial bus (USB) port.

37. The system as defined in claim 36 wherein the at least two PCI bus connectors are coupled to network card performing network functions, wherein the network functions are selected from the group of network functions comprising routers, switches, load balancers, bridges, firewalls, packet shapers, and servers.

38. The system as defined in claim 37 wherein the SBC further comprises a microprocessor that is selected from the group of microprocessors comprised of general purpose microprocessors and special purpose microprocessors.

39. The system as defined in claim 38 wherein the configuration software further comprises a software utility that enables drag-and-drop configuration of network components, to thereby simplify configuration of network components within the Open IP Services Platform.

40. The system as defined in claim 39 wherein the configuration software utilizes icons that are representative of the network components, wherein the icons are ActiveX modules that define the functions that are performed by the network components.

41. The system as defined in claim 40 wherein the switch/router board is a level 4 network device that is capable of communicating with other Open IP Services Platforms at wire speed.

42. The system as defined in claim 41 wherein the system further comprises a solid state refrigeration unit, where the refrigeration unit is disposed directly on a case of a hard drive, thereby directing cooling efforts directly on the most temperature sensitive device within the Open IP Services Platform.

43. A method for providing video-on-demand by creating a local network topology that decreases congestion on trunk lines between the local network structure and a global information network, and which stores videos on Open IP Services Platforms of the local network structure, said method comprising the steps of:
1) providing a local switch fabric network matrix as the local network topology, wherein the switch fabric network matrix is comprised of a plurality of Open IP Services Platforms;
2) providing a trunk line that is in communication with the switch fabric network matrix and the global information network, enabling transfer of data and voice communication therebetween; and
3) storing at least one digitized video on one of the plurality of Open IP Services Platforms, such that users within the local switch fabric network matrix that is storing the at least one digitized video receive video data of the at least one digitized video without having to receive the video data from outside the local switch fabric network matrix.

44. A local network topology that decreases congestion on trunk lines between the local network structure and a global information network, and which enables providing video-on-demand, said system comprising:
a local switch fabric network matrix as the local network topology, wherein the switch fabric network matrix is comprised of a plurality of Open IP Services Platforms;
at least one digitized video that is stored on at least one of the plurality of Open IP Services Platforms within the local switch fabric network matrix, wherein users within the local switch fabric network matrix receive video data of the at least one digitized video only from within the local switch fabric network matrix; and
a connection from the local switch fabric network matrix to a trunk line, wherein the trunk line is in communication with the switch fabric network matrix and the global information network, thereby enabling transfer of data and voice communication therebetween.
